(19) United States
(12) Patent Application Publication
(10) Pub. No.: US 2009/0065886 A1
(43) Pub. Date: Mar. 12, 2009

(54) SOLID-STATE IMAGE PICKUP DEVICE AND METHOD FOR MANUFACTURING THE SAME

(75) Inventor: Kouji TSUJIMURA, Kurokawa-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/204,537

(22) Filed: Sep. 4, 2008

(30) Foreign Application Priority Data
Sep. 7, 2007 (JP) 2007-233199

(51) Int. Cl. H01L 31/02; H01L 31/18

(52) U.S. Cl. 257/459; 438/98; 257/E31.124

(57) ABSTRACT

In a solid-state image pickup device, a thickness of an insulating film, a width and a thickness of wirings, a length of the wirings, or a diameter of bump portions formed on the wirings is formed so that a capacitance of a capacitor structure generated between a solid-state image sensor chip, and the wirings and the bump portions is not more than a desired value. Thereby, sensitivity of the solid-state image pickup device is not lowered at high-frequency driving.

### BACKGROUND OF THE INVENTION

1. Field of the Invention

The present invention relates to a solid-state image pickup device comprising through wirings for connecting a solid-state image sensor formed on the upper surface side of a semiconductor substrate to wirings formed on the lower surface side of the semiconductor substrate, and a method for manufacturing such a solid-state image pickup device.

2. Description of the Related Art

In recent years, the miniaturization and mass-production of solid-state image pickup devices composed of a CCD (charge coupled device) or a CMOS (complementary metal oxide semiconductor), used in digital cameras or mobile phones have been increasingly demanded.

As method for the miniaturization and mass-production of solid-state image pickup devices, a manufacturing method for a solid-state image pickup device and a solid-state image pickup manufactured by the method as shown in FIGS. 1A to 1D, have been proposed, and the manufacturing method comprises: joining (FIG. 1C) a solid-state image sensor wafer 10 (FIG. 1A) on which a large number of the light receiving sections of the solid-state image sensors to a translucent substrate 11 (glass wafer, FIG. 1B) on which spacers corresponding to the locations surrounding respective light receiving sections via the spacers; forming wirings for externally connecting to the lower surface side of the semiconductor substrate on which a solid-state image sensor is formed and through wirings for forming electrodes; and dividing the solid-state image pickup device (FIG. 1D) into respective solid-state image pickup devices 13, 13, 13 . . . through processes such as dicing (for example, refer to Japanese Patent Application Laid-Open No. 2001-351997 and Japanese Patent Application Laid-Open No. 2004-88082).

The configuration of a solid-state image pickup device having through wirings will be briefly described below. FIG. 2A is a sectional view showing a solid-state image pickup device and FIG. 2B is an enlarged diagram showing the essential parts encircled in FIG. 2A.

In a solid-state image pickup device 13 shown in FIG. 2 or FIG. 3A, a solid-state image sensor 21 and connecting terminals 22 are formed on the upper surface side, and the solid-state image sensor 21 is sealed by a cover glass 24 via spacers 23.

On a solid-state image sensor chip 20, as shown in FIG. 3B, wirings 25 for connecting to an external device provided on the lower surface of the solid-state image sensor chip 20, and through wirings 27 to connect connecting terminals 22 on the upper surface side to bump portions 26 are formed. Between the solid-state image sensor chip 20 and the through wirings 27, and between the solid-state image sensor chip 20 and the wiring 25 and the bump portions 26, an insulating film 28 is formed for insulation.

For solid-state image pickup devices having the above-described configuration, increase in the speed of actuating signal is further demanded in recent years in addition to miniaturization and mass-production. Increase in the speed of actuating signal causes the problem of lowered sensitivity of the solid-state image pickup device 13 due to the distortion of signals in the wirings 25, bump portions 26, and the through wirings 27 formed on the lower surface in the solid-state image sensor chip 20 shown in FIG. 2B. The distortion of signals may happen even at a driving frequency of a solid-state image sensor of about 6 MHz, and at the presently used driving frequency of 30 MHz it becomes a serious problem. In the future, the driving frequency may reach 75 MHz or more, and the problem will be further serious.

### SUMMARY OF THE INVENTION

However, since the insulating film 28 formed on the lower surface of the solid-state image sensor chip 20 is extremely thin (e.g. 1 μm), a capacitor structure in which the wirings 25 and the bump portions 26 on the lower surface, and the solid-state image sensor chip 20 work as electrodes is formed. Thereby, unnecessary charges are accumulated between the wirings 25 and the bump portions 26 on the lower surface, and the solid-state image sensor chip 20 causing the delay and distortion of signals and lowering the sensitivity of the solid-state image pickup device.

The present invention is developed in consideration for such problems. The present invention aims to provide a solid-state image pickup device that lowers the capacitance of the capacitor structure formed in the solid-state image pickup device to reduce the distortion of signals, and does not lower the sensitivity in high-frequency driving; and a method for manufacturing such a solid-state image pickup device.

To achieve the above-described object, a solid-state image pickup device according to an aspect of the present invention comprises: a semiconductor substrate; solid-state image sensors formed on an upper surface of the semiconductor substrate; and wirings formed on a lower surface of the semiconductor substrate and connected to the through wirings, wherein a thickness of an insulating film insulating the wirings from the semiconductor substrate, a width and a thickness of the wirings, a length of the wirings, or a diameter of bump portions formed on the wirings is formed so that a capacitance between the semiconductor substrate and the wiring is not more than a desired value.

In the above-described solid-state image pickup device, the value of the capacitance may be not more than 2 pF; the thickness of the insulating film may be not less than 2 μm and not more than 10 μm; the width of the wiring may be not more than 200 μm and not less than 10 μm; and the diameter of the bump portions is not more than 200 μm and not less than 50 μm.

According to the aspect of the present invention, in a solid-state image pickup device, a solid-state image sensor is formed on a upper surface side of a semiconductor substrate, and wirings and electrodes to be connected to external devices are formed on a lower surface side of the semiconductor substrate. The solid-state image sensor is connected to the wirings by through wirings formed in the semiconductor substrate, and an insulating film is formed between the semiconductor substrate and the wirings.

At this time, a thickness of the insulating film, a width and a thickness of the wirings, a length of the wirings, or a diameter of bump portions formed on the wirings is formed so that a capacitance of a capacitor structure in which the semiconductor substrate and the wirings work as electrodes is not more than a desired value. Thereby, unnecessary charges are not accumulated between the wirings and the semiconductor substrate; delay and distortion of signals are prevented; and the sensitivity lowering of the solid-state image pickup device at high-frequency operation is prevented.

In addition, in the solid-state image pickup device, the thickness of the insulating film and the width of the wirings are adjusted so that a value of the capacitance may be not more than 2 pF. They are formed so that the thickness of the insulating film may be not less than 2 μm and not more than 10 μm; the width of the wirings may be not more than 200 μm and not less than 10 μm; and the diameter of the bump portions may be not more than 200 μm and not less than 50 μm.

As described above, according to the aspects of the present invention, by adjusting a thickness of an insulating film insulating wirings from a semiconductor substrate, a width and a thickness of the wirings, a length of the wirings, or a diameter of bump portions formed on the wirings, a capacitance of a capacitor structure formed in a solid-state image pickup device is lowered. Thereby, a solid-state image pickup device and a method for manufacturing the solid-state image pickup device which eliminates distortion of signals and does not lower a sensitivity at high-frequency driving, can be provided.

### BRIEF DESCRIPTION OF THE DRAWINGS

FIGS. 1A to 1D are perspective views of a wafer and a substrate for explaining a method for manufacturing a solid-state image pickup device;

FIG. 2A is a sectional side view showing a solid-state image pickup device and

FIG. 2B is an enlarged diagram showing its essential part which is encircled in FIG. 2A;

FIGS. 3A and 3B are perspective views showing the appearances of the upper and lower surfaces of a solid-state image pickup device;

FIGS. 4A to 4C are sectional side views explaining the procedures for forming through holes; and

FIG. 5 is a plan view showing the wiring state on the lower surface of a solid-state image pickup device.

### DETAILED DESCRIPTION OF THE PREFERRED EMBODIMENTS

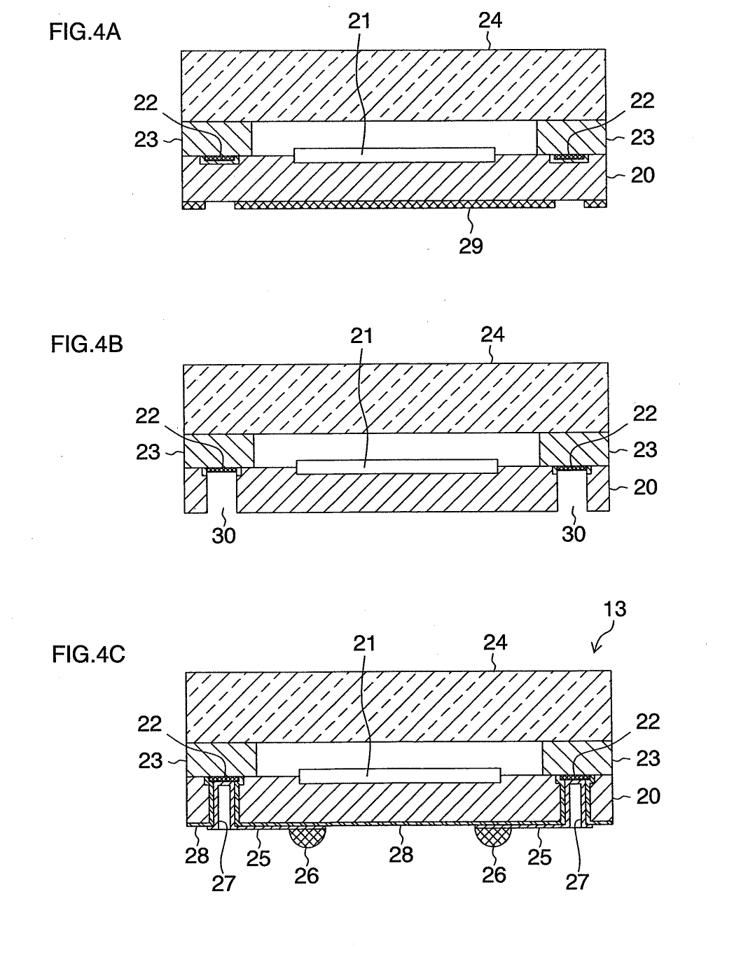

A preferred embodiment of a solid-state image pickup device and a method for manufacturing the solid-state image pickup device according to the present invention will be described below in detail referring to the attached drawings. FIGS. 4A and 4B are sectional views showing the procedures for forming through wirings in a solid-state image pickup device.

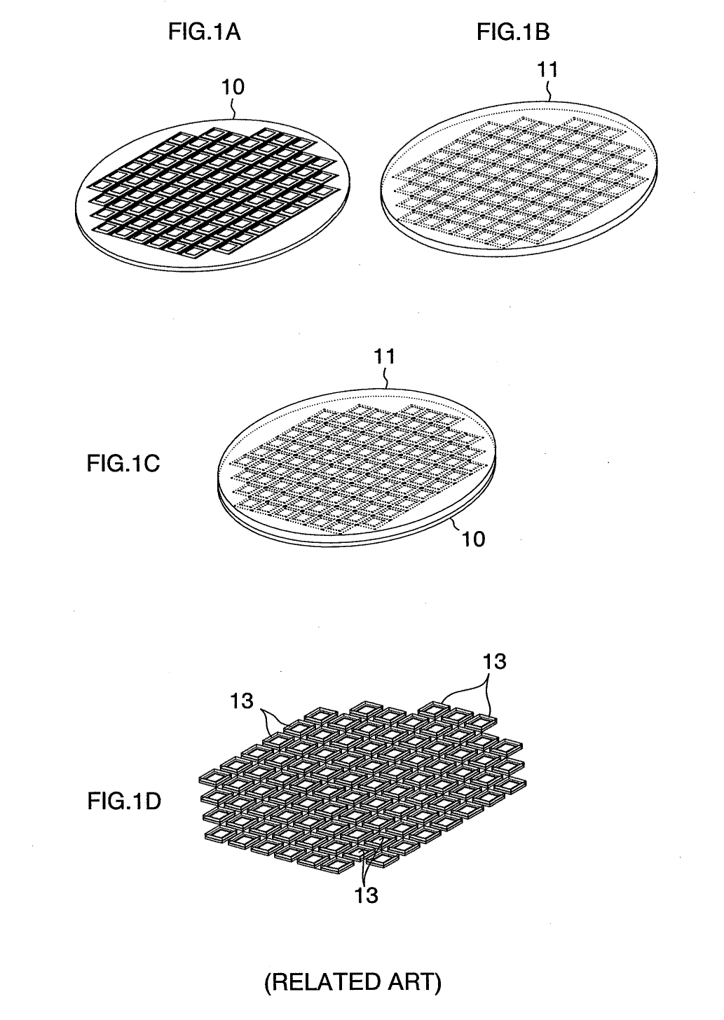

In the manufacturing process of a solid-state image pickup device 13 shown in FIGS. 1A to 1D, first, a solid-state image sensor wafer 10 is joined to a translucent substrate 11.

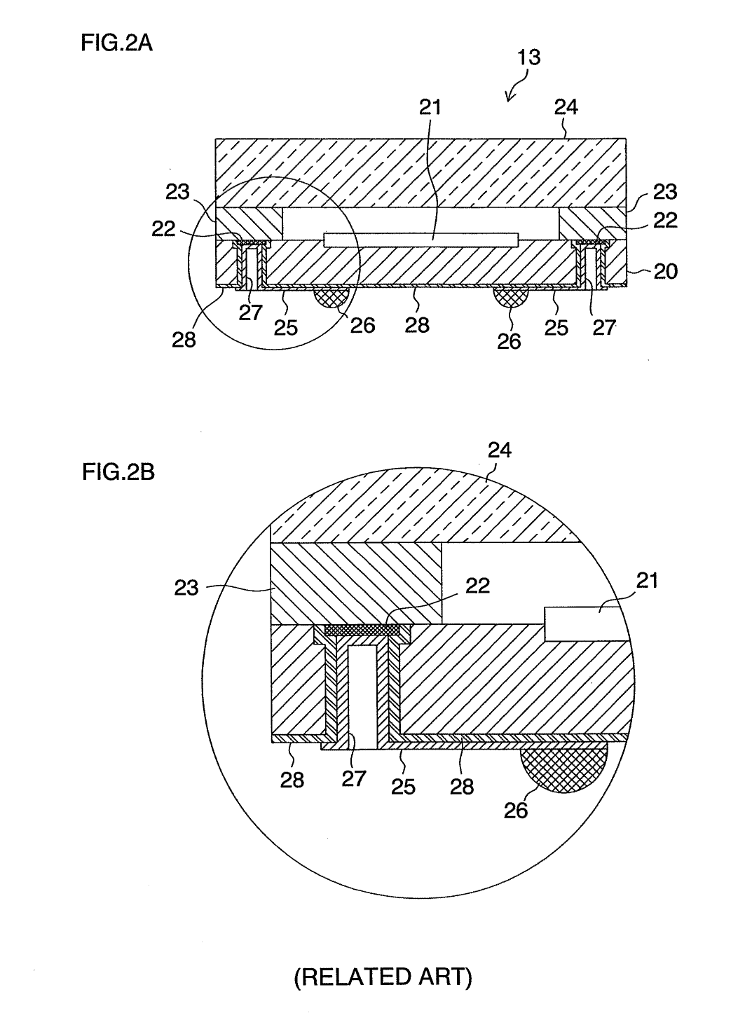

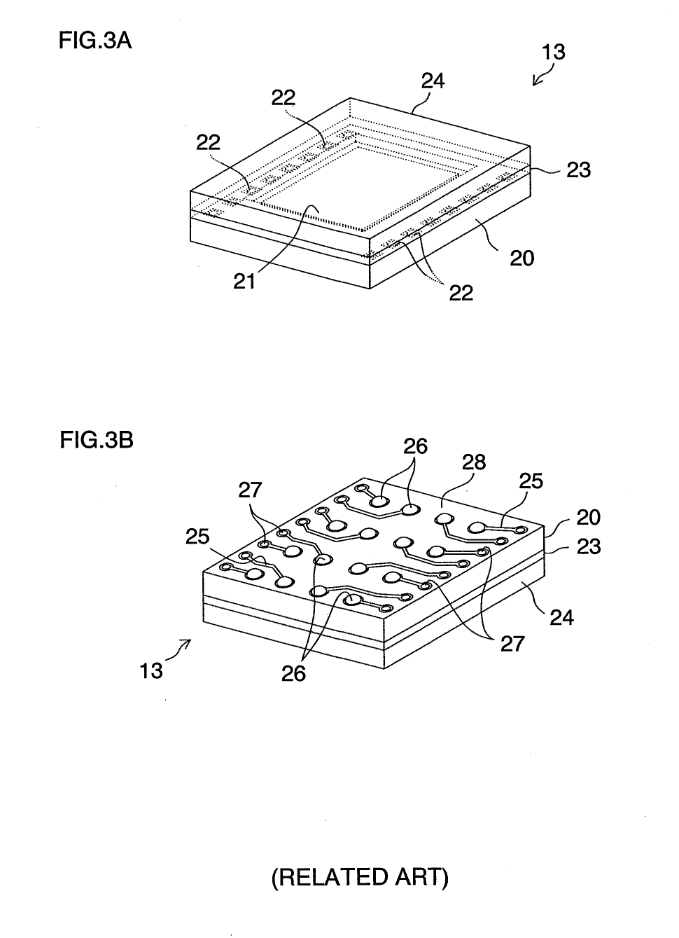

The solid-state image sensor wafer 10 shown in FIG. 1A is a disk-shaped single-crystal silicon substrate on which a large number of solid-state image sensors 21 and connecting terminals 22 shown in FIG. 2A are formed by an ordinary semiconductor element manufacturing process, and the thickness of the solid-state image sensor wafer 10 is, for example, about 300 μm.

Each of the solid-state image sensors 21 formed on the solid-state image sensor wafer 10 comprises a photo diode which is a light receiving element, a transfer electrode which transfers excitation voltage to the exterior, a light-shielding film having an opening, and an interlayer insulating film. Furthermore, in the solid-state image sensor 21, an inner lens is formed on the interlayer insulating film, a color filter is provided on the inner lens via an intermediate layer, and a micro lens and the like is provided on the color filter via the intermediate layer.

The translucent substrate 11 is a disk-shaped substrate having a thickness of, for example, about 500 μm composed of transparent glass having a coefficient of thermal expansion similar to that of silicon, for example, Pyrex (registered trademark) glass. On the lower surface of the translucent substrate 11, a large number of frame-shaped spacers 23 are joined in the positions of the solid-state image sensors 21 on the solid-state image sensor wafer 10.

The spacers 23 are composed of an inorganic material having properties such as the coefficient of thermal expansion similar to those of the solid-state image sensor wafer 10 and the translucent substrate 11, for example, polycrystalline silicon. The spacers 23 are formed by etching the polycrystalline silicon substrate joined to the translucent substrate 11 using an adhesive and the like, or by adhering material previously shaped like spacers 23 to the translucent substrate 11. When the cross-section of a part of each spacer 23 is viewed, the width and thickness of the cross-section are about 200 μm and about 100 μm, respectively.

Next, in the solid-state image sensor wafer 10 on which the translucent substrate 11 is joined via spacers 23, through holes for forming through wirings 27 shown in FIGS. 2A and 2B are formed from the lower surface side in locations facing the connecting terminals 22 formed on the upper surface of the solid-state image sensor wafer 10.

As shown in FIG. 4A, in the process for forming through holes, a resist mask 29 is formed using photolithography on the lower surface of the solid-state image sensor wafer 10 other than areas where the through holes will be formed. Next, as shown in FIG. 4B, through holes 30 are formed in the solid-state image sensor wafer 10 using plasma etching. By the through holes 30, the lower surface sides of the connecting terminals 22 are exposed in the through holes 30. Then, the resist mask 29 is removed by ashing.

An insulating film 28 is formed on the lower surface of the solid-state image sensor wafer 10 where the connecting terminals 22 are exposed in the through holes 30. The insulating film 28 is formed using, for example, chemical vapor deposition (CVD). In the process for forming the insulating film 28, since the insulating film 28 is also formed on the connecting terminals 22 exposed in the through holes 30, the conduction of the connecting terminals 22 to a conductive paste for forming through wirings 27 filled in the through holes 30 is interfered. Therefore, after forming the insulating film 28, a resist mask is again formed using photolithography on the lower surface of the solid-state image sensor wafer 10 other than the area of the insulating film 28 on the connecting terminals 22, and only the insulating film 28 on the connecting terminals 22 that is not masked is removed using plasma etching. Then, the resist mask is removed by ashing.

At this time, the insulating film 28 is formed to have a final thickness of not less than 2 μm and not more than 10 μm. Thereby, the value of the capacitance of the capacitor structure formed between the solid-state image sensor chip 20 and the wiring 25 is adjusted to be not more than 2 pF, which is not more than the desired value; unnecessary charges are not accumulated between the solid-state image sensor chips 20 and the wirings 25; the delay of the signal and the occurrence of distortion is prevented; and the sensitivity lowering of the solid-state image pickup device in high-frequency operation is prevented.

After forming the insulating film 28, in the solid-state image sensor wafer whose connecting terminals 22 are again exposed in the through holes 30, a conductive paste forming through wirings 27 is filled in the through holes 30. For filling the conductive paste, vacuum screen printing is used. The filled conductive paste is cured by heating the solid-state image sensor wafer 10.

As shown in FIG. 4C, wirings 25 for connecting to external devices are formed on the lower surface side of the solid-state image sensor wafer 10 in which through wirings 27 are formed, and a bump portion 26 is formed on an end of each wiring 25. In the formation of wirings 25, a resist mask is formed using photolithography on the lower surface of the solid-state image sensor wafer 10, the lower surface side of the solid-state image sensor wafer 10 is immersed in a plating solution, to form wirings 25 by electroless plating, and finally, the resist mask is removed using a solution and the like.

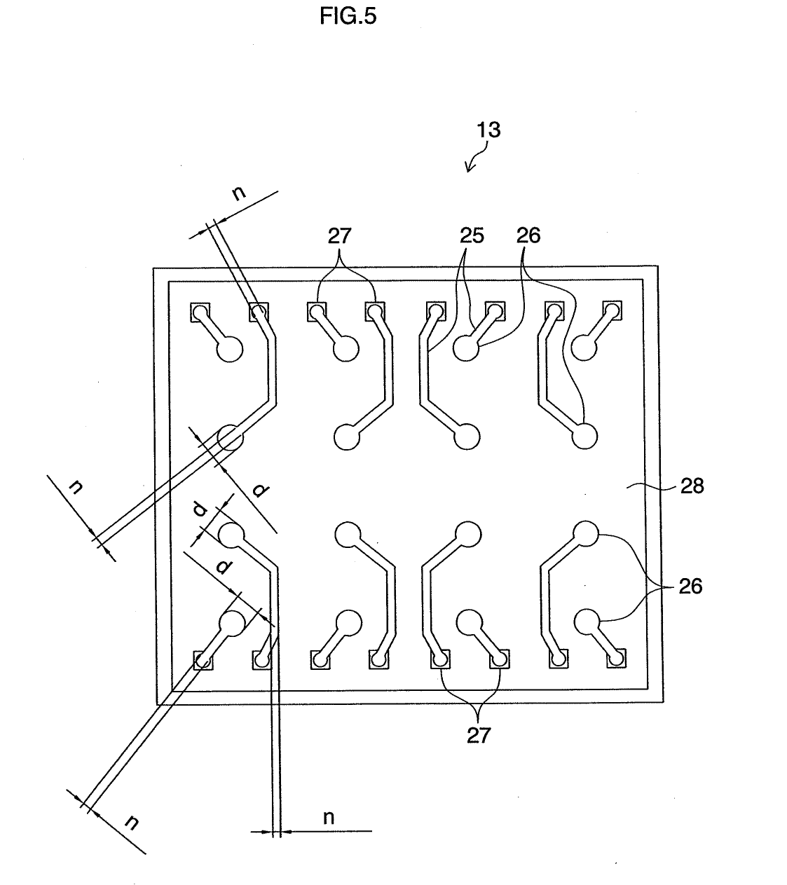

At this time, as shown in FIG. 5, each wiring 25 is formed so as to have a width n of not more than 200 μm and not less than 10 μm. The thickness of each wiring 25 is preferably not less than 10 μm to meet the reduction of the width n of the wiring 25, and more preferably not less than 20 μm. Each of the bump portions 26 is formed so as to have a diameter d of not more than 200 μm and not less than 50 μm.

Furthermore, when the insulating film 28 is composed of SiO2, and the relative permeability of the insulating film 28 is 3.9, the length of the wiring 25 is preferably not more than one-fourth the length of the wiring formed by a gold wire by wire bonding, which is a heretofore known wiring system.

Thereby, the value of the capacitance of the capacitor structure formed between the solid-state image sensor chip 20, and the wirings 25 and the bump portions 26 is adjusted to be not more than 2 pF, which is the desired value, unnecessary charges are not accumulated between the solid-state image sensor chip 20, and the wirings 25 and the bump portions 26; the delay of the signal and the occurrence of distortion is prevented; and the sensitivity lowering of the solid-state image pickup device in high-frequency operation can be prevented.

As described above, according to a solid-state image pickup device and a method for manufacturing the solid-state image pickup device of the present invention, by adjusting a thickness of an insulating film formed on an lower surface, a width and a thickness of wirings, a length of the wirings, or a diameter of bump portions formed on the wirings, a capacitance of a capacitor structure formed between a solid-state image sensor chip, and the wirings and the bump portions is reduced; unnecessary charges are not accumulated between the solid-state image sensor chip, and the wirings and the bump portions; the delay of the signal and the occurrence of distortion is prevented in the solid-state image pickup device; and the sensitivity lowering of the solid-state image pickup device in high-frequency operation can be prevented.

Although both the thickness of the insulating film and the width of the wirings formed on the lower surface are adjusted in the present embodiment, of the invention of the present application is not limited thereto, but only one of the thickness of the insulating film and the width of the wirings may also be adjusted.

What is claimed is:

1. A solid-state image pickup device comprising:
a semiconductor substrate;
solid-state image sensors formed on an upper surface of the semiconductor substrate;
through wirings penetrating the semiconductor substrate; and
wirings formed on a lower surface of the semiconductor substrate and connected to the through wirings, wherein
a thickness of an insulating film insulating the wirings from the semiconductor substrate, a width and a thickness of the wirings, a length of the wirings, or a diameter of bump portions formed on the wirings is formed so that a capacitance between the semiconductor substrate and the wiring is not more than a desired value.

2. The solid-state image pickup device according to claim 1, wherein
the value of the capacitance is not more than 2 pF.

3. The solid-state image pickup device according to claim 1, wherein
the thickness of the insulating film is not less than 2 μm and not more than 10 μm.

4. The solid-state image pickup device according to claim 1, wherein
the width of the wiring is not more than 200 μm and not less than 10 μm.

5. The solid-state image pickup device according to claim 1, wherein
the diameter of the bump portions is not more than 200 μm and not less than 50 μm.

6. A method for manufacturing a solid-state image pickup device comprising:
forming solid-state image sensors on an upper surface of a semiconductor substrate; and
forming through wirings connecting wirings formed on a lower surface of the semiconductor substrate to the solid-state image sensors, on the semiconductor substrate, wherein
a thickness of an insulating film insulating the wirings from the semiconductor substrate, a width and a thickness of the wirings, a length of the wirings, or a diameter of bump portions formed on the wirings is formed so that a capacitance between the semiconductor substrate and the wiring is not more than a desired value.

7. The method for manufacturing a solid-state image pickup device according to claim 6, wherein
the value of the capacitance is not more than 2 pF.

8. The method for manufacturing a solid-state image pickup device according to claim 6, wherein
the thickness of the insulating film is not less than 2 μm and not more than 10 μm.

9. The method for manufacturing a solid-state image pickup device according to claim 6, wherein
the width of the wiring is not more than 200 μm and not less than 10 μm.

10. The method for manufacturing a solid-state image pickup device according to claim 6, wherein
the diameter of the bump portions is not more than 200 μm and not less than 50 μm.
